(19) United States
(12) Patent Application Publication
(10) Pub. No.: US 2026/0013370 A1
(43) Pub. Date: Jan. 8, 2026

(54) DISPLAY DEVICE AND METHOD OF FABRICATING THE SAME

(71) Applicant: Samsung Display Co., LTD., Yongin-si (KR)

(72) Inventors: Byeong Kyu PARK, Yongin-si (KR); Hyo Chang KIM, Yongin-si (KR); Han Sun RYOU, Yongin-si (KR); Young Eun OH, Yongin-si (KR)

(21) Appl. No.: 19/169,922

(22) Filed: Apr. 3, 2025

(30) Foreign Application Priority Data
Jul. 3, 2024 (KR) 10-2024-0087292

(51) Int. Cl. H10K 59/80; G06F 1/16; H10K 59/12; H10K 77/10; H10K 102/00

(52) U.S. Cl. CPC H10K 59/8722; G06F 1/1652; H10K 59/1201; H10K 77/111; H10K 2102/311

(57) ABSTRACT

A display device including: a display panel; a base member on a surface of the display panel; a support member on a surface of the base member; and a spacer on the surface of the base member. The base member includes: a base film; a fourth adhesive layer between the base film and the display panel; and a fifth adhesive layer between the base film and the support member and between the base film and the spacer, and the base film, the fourth adhesive layer, and the fifth adhesive layer are integrally formed.

### CROSS-REFERENCE TO RELATED APPLICATION

The present application claims priority to and the benefit of Korean Patent Application No. 10-2024-0087292, filed on Jul. 3, 2024, in the Korean Intellectual Property Office, the entire disclosure of which is incorporated herein by reference.

### BACKGROUND

### 1. Field

Aspects of embodiments of the present disclosure relate to a display device and a method of fabricating the same.

### 2. Description of the Related Art

Display devices should have certain characteristics, such as good luminance, low driving voltage, fast response speed, and a wide range of color reproduction. Display devices are being employed by a variety of devices including smart phones. One type of display device includes a display panel including organic light-emitting elements. In an organic light-emitting element, a cathode electrode and an anode electrode are disposed around (e.g., on either side of) an organic emissive layer. When a voltage is applied to the cathode electrode and the anode electrode, visible light is generated in the organic emissive layer connected to the two electrodes.

A display device may be formed by stacking a variety of members, such as a polarizing member, a cover window, a support member, and a spacer, on a display panel. To prevent the display panel from being damaged during the process of stacking the support member and the spacer on the display panel, a base member may be disposed between the display panel and the support member and between the display panel and the spacer.

### SUMMARY

Embodiments of the present disclosure provide a method of fabricating a display device including a simplified process of disposing a base film, a support member, and a spacer on a display panel, and a display device fabricate by the method.

However, aspects and features of the present disclosure are not limited to those set forth herein. The above and other aspects and features of the present disclosure will become more apparent to one of ordinary skill in the art to which the present disclosure pertains by referencing the detailed description of the present disclosure, given below.

According to an embodiment of the present disclosure, a display device includes a display panel, a base member on a surface of the display panel, a support member on a surface of the base member, and a spacer on the surface of the base member. The base member includes a base film, a fourth adhesive layer between the base film and the display panel, and a fifth adhesive layer between the base film and the support member and between the base film and the spacer, and the base film, the fourth adhesive layer, and the fifth adhesive layer are integrally formed.

The display device may further include a polarizing member on a surface of the display panel opposite to the base member; a cover window on a surface of the polarizing member opposite to the display panel; a protective member on a surface of the cover window opposite to the polarizing member; a first adhesive layer between the protective member and the cover window; a second adhesive layer between the cover window and the polarizing member and on a surface of the cover window facing the polarizing member; and a third adhesive layer between the cover window and the polarizing member and on the surface of the polarizing member facing the cover window.

The display device may further include a sixth adhesive layer between the support member and the spacer. The display panel may have a bending area configured to be bent, and the support member and the spacer may come into contact with each other when the display panel is bent.

The bending area of the display panel may be between the support member and the spacer.

The display device may further include a bending protective member on the bending area of the display panel and a cover member covering a part of the bending protective member and a part of the display panel.

The fifth adhesive layer may have an opening therein formed by removing a part of the fifth adhesive layer, and the support member may have an opening formed therein.

The opening of the support member may correspond to the opening in the fifth adhesive layer.

According to an embodiment of the present disclosure, a method of fabricating a display device includes preparing a base member including a base film, a fourth adhesive layer, and a fifth adhesive layer integrally formed together; attaching the base film to a display panel by the fourth adhesive layer; and attaching a support member and a spacer to the base film by the fifth adhesive layer.

The base member may include: a fourth cover film covering the fourth adhesive layer; and a fifth cover film covering the fifth adhesive layer. The attaching the base film to the display panel may include: removing the fourth cover film; and bringing the fourth adhesive layer into contact with the display panel.

The method may further include, after the attaching the base film to the display panel, removing a part of the base film.

The display panel may have a bending area at where a part of the display panel is configured to be bent, and the removing the part of the base film may include removing the base film corresponding to the bending area of the display panel.

The removing the part of the base film may include: removing the base film on the bending area of the display panel along with the fourth adhesive layer and the fifth adhesive layer on the bending area of the display panel.

The attaching the support member and the spacer to the base film may include: removing the fifth cover film; and bringing the support member and the spacer into contact with the fifth adhesive layer.

The method may further include: after the attaching the support member and the spacer to the base film, bending a part of the display panel; and attaching the spacer to the support member.

The spacer may include: a sixth adhesive layer formed integrally with the spacer; and a sixth cover film covering the sixth adhesive layer. The attaching the spacer to the support member may include: removing the sixth cover film; and bringing the sixth adhesive layer into contact with the support member.

The method may further include: disposing a polarizing member on the display panel; disposing a cover window on the polarizing member; and disposing a protective member on the cover window.

The polarizing member may include a third adhesive layer formed integrally with the polarizing member. The cover window may include a second adhesive layer formed integrally with the cover window, and the disposing the cover window on the polarizing member may include bringing the second adhesive layer into contact with the third adhesive layer.

The protective member may include a first adhesive layer formed integrally with the protective member, and the disposing the protective member on the cover window may include bringing the first adhesive layer into contact with the cover window.

The method may further include: disposing a bending protective member on the display panel; and disposing a cover member to cover a part of the bending protective member and a part of the display panel.

The bending protective member and the cover member may be on a surface of the display panel on which the polarizing member is arranged.

According to an embodiment of the present disclosure, a fourth adhesive layer that attaches a base film to a display panel and a fifth adhesive layer that attaches the base film to a support member and a spacer are formed integrally with the base film in a display device so that a process of stacking a separate adhesive layer on the support member and the spacer can be omitted. As a result, the process of disposing the base film, the support member, and the spacer on the display panel can be simplified.

The aspects and features according to embodiments of the present disclosure are not limited to those mentioned above and more aspects and feature are included in the following description of the present disclosure and would be understood by one of ordinary skill in the art to which the disclosure pertains.

### BRIEF DESCRIPTION OF THE DRAWINGS

The above and other aspects and features of the present disclosure will become more apparent by describing, in detail, embodiments thereof with reference to the attached drawings, in which:

FIG. 1 is a perspective view of a display device according to an embodiment of the present disclosure in an unfolded state.

FIG. 2 is a perspective view of the display device shown in FIG. 1 in a folded state.

FIG. 3 is a perspective view of a display device according to another embodiment of the present disclosure in an unfolded state.

FIG. 4 is a perspective view of the display device shown in FIG. 3 in a folded state

FIG. 5 is a plan view of a display panel of a display device according to an embodiment of the present disclosure in an unfolded state.

FIG. 6 is a bottom view of the display panel shown in FIG. 5.

FIG. 7 is a plan view of the display panel shown in FIG. 4 in a bent state.

FIG. 8 is a cross-sectional view taken along the line A-A′ in FIG. 7.

FIG. 9 is a cross-sectional view of the display panel shown in FIG. 8.

FIG. 10 is a flowchart describing steps of a method of fabricating the display device according to an embodiment of the present disclosure.

FIG. 11 is a view of a display panel prepared according to a method of fabricating a display device.

FIG. 12 is a view of a base member disposed on a display panel according to a method of fabricating a display device.

FIG. 13 is a view of a fourth cover film being removed according to a method of fabricating a display device.

FIG. 14 is a view of a base member disposed on the display panel according to a method of fabricating a display device.

FIG. 15 is a view of a part of the base member that is cut according to a method of fabricating a display device.

FIG. 16 is a view of the cut part of the base member being removed according to a method of fabricating a display device.

FIG. 17 is a view of a fifth cover film being removed according to a method of fabricating a display device.

FIGS. 18 and 19 are views of a support member and a spacer being attached to the base member according to a method of fabricating a display device.

FIG. 20 is a view of a sixth cover film that is removed and the display panel being bent according to a method of fabricating a display device.

FIG. 21 is a view of the display panel in the bent state and the support member and the spacer in contact with each other according to a method of fabricating a display device.

FIG. 22 is a block diagram of an electronic device according to one embodiment of the present disclosure.

FIG. 23 is a schematic diagram of an electronic device according to various embodiments of the present disclosure.

### DETAILED DESCRIPTION

Aspects and features of the present disclosure, and methods to achieve them, will become apparent from the description of embodiments that follows with reference to the accompanying drawings. However, the present disclosure is not limited to embodiments disclosed herein and may be implemented in various different ways. Some embodiments are described below to ensure that this disclosure of the present disclosure is thorough and fully conveys the scope of the present disclosure to those skilled in the art. It is to be noted that the scope of the present disclosure is defined only by the claims and their equivalents.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Hereinafter, embodiments of the present disclosure will be described, in detail, with reference to the accompanying drawings.

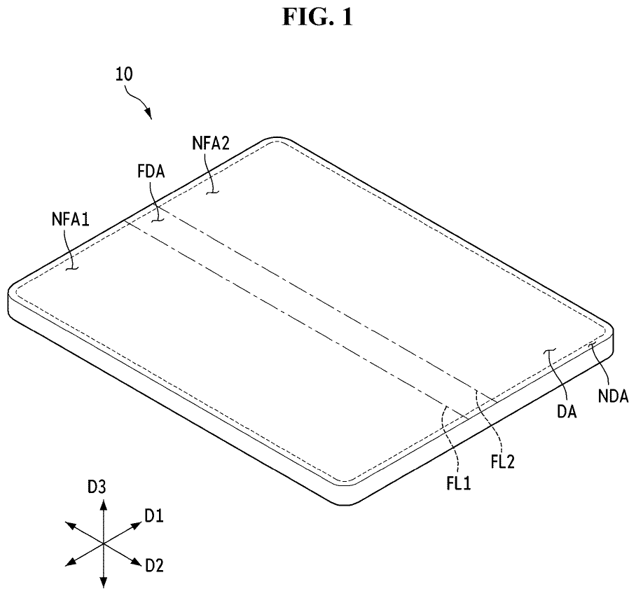

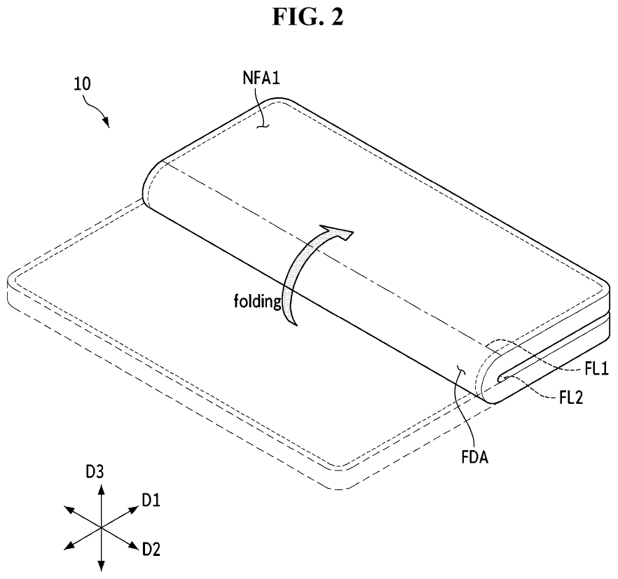

FIG. 1 is a perspective view of a display device 10 according to an embodiment of the present disclosure in an unfolded state. FIG. 2 is a perspective view of the display device 10 in a folded state.

Referring to FIGS. 1 and 2, FIG. 1 shows a first state in which the display device 10 is unfolded (e.g., when the display device 10 is not folded over folding lines FL1 and FL2), and FIG. 2 shows a second state in which the display device 10 is folded over (or folded at or between) the folding lines FL1 and FL2.

As illustrated herein, the display device 10 is for displaying moving images and/or still images, but this merely an example. The display device 10 may be used as the display screen of a portable electronic device, such as a mobile phone, a smart phone, a tablet PC, a smart watch, a watch phone, a mobile communications terminal, an electronic notebook, an electronic book, a portable multimedia player (PMP), a navigation device, and a ultra-mobile PC (UMPC), as well as the display screen of various other products, such as a television, a notebook, a monitor, a billboard, and an Internet of Things (IoT) device. In some embodiments, the display device 10 may be used as a display screen applied to the center fascia of a vehicle. In the following description, the display device 10 is illustrated as being a smartphone, but this is merely an example, and the present disclosure is not limited thereto.

The display device 10 may be a light-emitting display device, such as an organic light-emitting display device including organic light-emitting diodes, a quantum-dot light-emitting display device including quantum-dot light-emitting layer, an inorganic light-emitting display device including an inorganic semiconductor, and a micro light-emitting display device including micro light-emitting diodes (LED). In the following description, an organic light-emitting display device is described as an example of the display device 10, but the present disclosure is not limited thereto.

As shown in FIGS. 1 and 2, a first direction D1 may refer to a direction parallel to a side of the display device 10, for example, the horizontal direction of the display device 10 when viewed from the top. A second direction D2 may refer to a direction parallel to another side of the display device 10 that meets the side of the display device 10, for example, the vertical direction of the display device 10 when viewed from the top. A third direction D3 may refer to the thickness direction of the display device 10.

The display device 10 may have a quadrangular shape, such as a rectangular shape, when viewed from the top. Each of the corners of the display device 10 may form a right angle or may be rounded when viewed from the top. The front surface of the display device 10 may have two shorter sides extending in the first direction D1 and two longer sides extending in the second direction D2.

The display device 10 may have a display area DA and a non-display area NDA. The shape of the display area DA may follow (or may correspond to) the shape of the display device 10 when viewed from the top. For example, when the display device 10 has a rectangular shape when viewed from the top, the display area DA may also have a rectangular shape when viewed from the top.

The display area DA may include a plurality of pixels to display images. The non-display area NDA may not include pixels and, thus, may not display an image. The non-display area NDA may be disposed around the display area DA. The non-display area NDA may surround (e.g., may extend around a periphery of) the display area DA, but embodiments of the present disclosure are not limited thereto. In some embodiments, the display area DA may be partially surrounded by the non-display area NDA.

The display device 10 may stay in a first state when it is unfolded or a second state when it is bent. The display device 10 may be folded inwardly so that a part of the display device DA faces the other part (a so-called in-folding manner), as shown in FIG. 2. In such an embodiment, a part of the front surface of the display device 10 may face the other part when it is folded. In another embodiment, the display device 10 may be folded outwardly (a so-called out-folding manner) such that a part of the rear surface faces the other part when it is folded.

The display device 10 may have a folding area FDA, a first non-folding area NFA1, and a second non-folding area NFA2. The display device 10 can be bent or folded at the folding area FDA but cannot be (e.g., is not designed or configured to be) bent or folded at the first non-folding area NFA1 and the second non-folding area NFA2. According to an embodiment of the present disclosure, the first non-folding area NFA1 and the second non-folding area NFA2 may be flat areas of the display device 10.

The first non-folding area NFA1 may be disposed on one side, for example, the left side, of the folding area FDA. The second non-folding area NFA2 may be disposed on the opposite side, for example, the right side, of the folding area FDA. The folding area FDA may be defined by (e.g., defined between) the first folding line FL1 and the second folding line FL2 where the display device 10 can be bent to have a curvature (e.g., a predetermined curvature). The first folding line FL1 may be the boundary between the folding area FDA and the first non-folding area NFA1, and the second folding line FL2 may be the boundary between the folding area FDA and the second non-folding area NFA2.

The first folding line FL1 and the second folding line FL2 may extend in the second direction D2 as shown in, for example, FIGS. 1 and 2, and the display device 10 may be folded along the second direction D2. Accordingly, the length of the display device 10 in the first direction D1 may be reduced to about half so that the display device 10 is easier to carry.

When the first folding line FL1 and the second folding line FL2 extend in the second direction D2 as shown in, for example, FIGS. 1 and 2, the length of the folding area FDA in the second direction D2 may be larger than the length thereof in the first direction D1. In addition, the length of the first non-folding area NFA1 in the second direction D2 may be larger than the length of the first non-folding area NFA1 in the first direction D1. The length of the second non-folding area NFA2 in the second direction D2 may be larger than the length of the second non-folding area NFA2 in the first direction D1.

Each of the display area DA and the non-display area NDA may overlap at least one of the folding area FDA, the first non-folding area NFA1, and the second non-folding area NFA2. In the embodiment shown in FIGS. 1 and 2, each of the display area DA and the non-display area NDA overlaps the folding area FDA, the first non-folding area NFA1, and the second non-folding area NFA2.

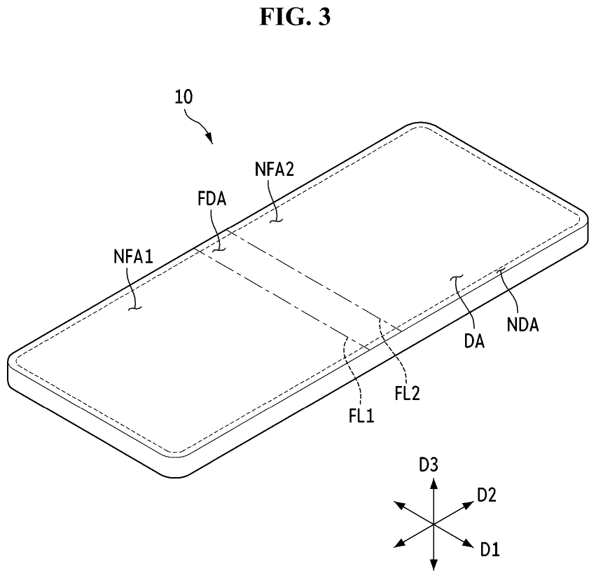

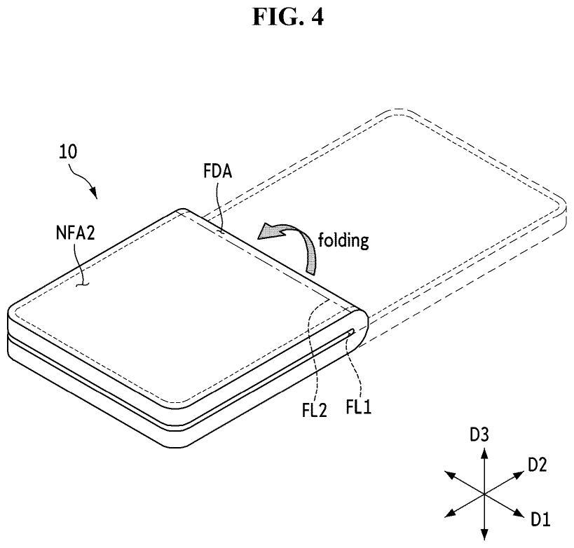

FIG. 3 is a perspective view of a display device 10 according to another embodiment of the present disclosure in an unfolded state. FIG. 4 is a perspective view of the display device 10 shown in FIG. 3 in a folded state.

The embodiment shown in FIGS. 3 and 4 is substantially identical to the embodiment shown in FIGS. 1 and 2 except that a first folding line FL1 and a second folding line FL2 extend in the first direction D1 and the display device 10 can be folded in the second direction D2 so that the length of the display device 10 in the second direction D2 can be reduced by approximately half. Therefore, the elements, components, and/or configurations of the embodiment shown in FIGS. 3 and 4 identical or substantially similar to those of the embodiment shown in FIGS. 1 and 2 will not be described or only briefly described to avoid redundancy.

Referring to FIGS. 3 and 4, FIG. 3 shows a first state in which the display device 10 is unfolded (e.g., is not folded at the folding lines FL1 and FL2), and FIG. 4 shows a second state in which the display device 10 is folded at (or between) the folding lines FL1 and FL2.

In the first state in which the display device 10 is unfolded, the longer sides of the display device 10 may extend in the second direction D2, and the shorter sides of the display device 10 may extend in the first direction D1.

The first folding line FL1 and the second folding line FL2 may extend in the first direction D1 as shown in, for example, FIGS. 3 and 4, and the display device 10 may be folded in the second direction D2.

The first non-folding area NFA1 may be disposed on one side, for example, the lower side, of the folding area FDA. The second non-folding area NFA2 may be disposed on the opposite side, for example, the upper side, of the folding area FDA.

When the first folding line FL1 and the second folding line FL2 extend in the first direction D1 as shown in, for example, FIGS. 3 and 4, the length of the folding area FDA in the first direction D1 may be larger than the length thereof in the second direction D2. In addition, the length of the first non-folding area NFA1 in the second direction D2 may be larger than the length of the first non-folding area NFA1 in the first direction D1. The length of the second non-folding area NFA2 in the second direction D2 may be larger than the length of the second non-folding area NFA2 in the first direction D1.

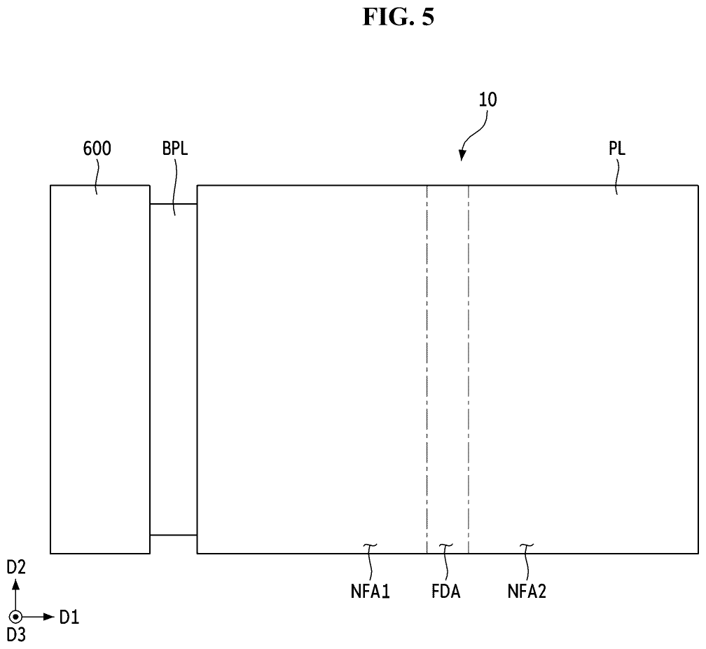

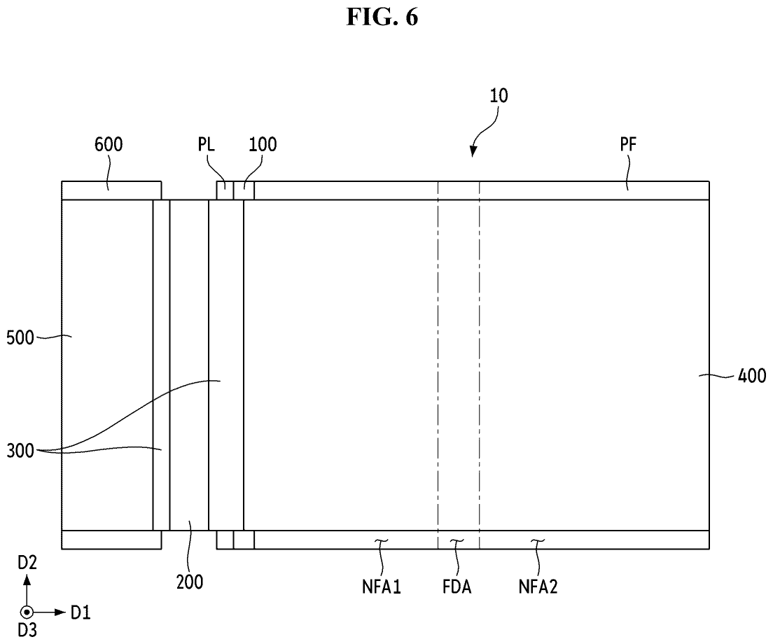

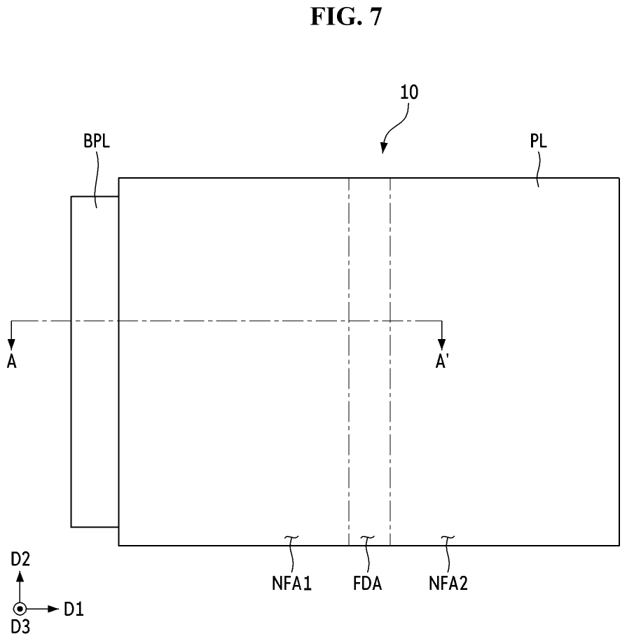

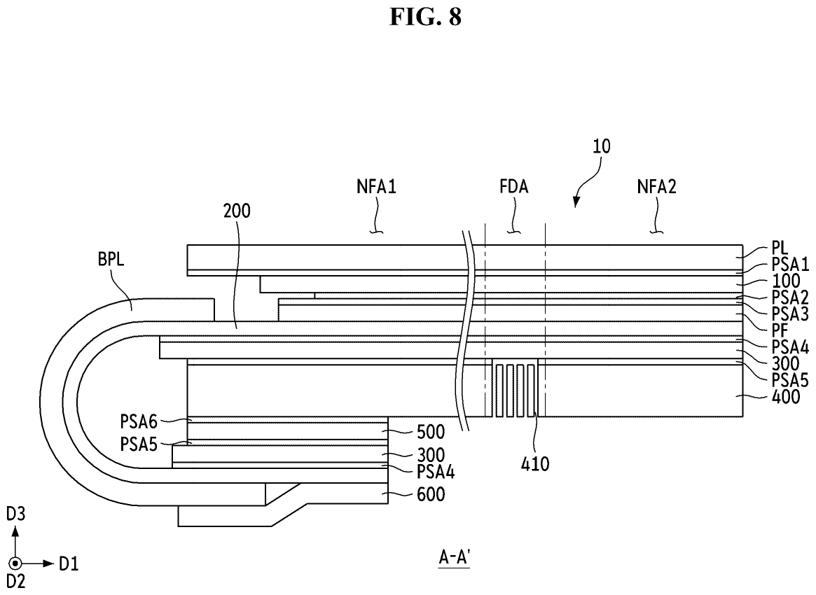

FIG. 5 is a plan view of a display panel 200 of the display device 10 according to an embodiment of the present disclosure in an unfolded state. FIG. 6 is a bottom view of the display device 10 shown in FIG. 5. FIG. 7 is a plan view of the display panel 200 of the display device 10 shown in FIG. 5 in a bent state. FIG. 8 is a cross-sectional view taken along the line A-A′ in FIG. 7.

Referring to FIGS. 5 to 8, the display device 10, according to an embodiment of the present disclosure, may include a protective member PL, a cover window 100, a polarizing member PF, a display panel 200, a bending protective member BPL, a base member (or base film) 300, a support member 400, a spacer 500, a circuit board, and a cover member 600.

The protective member PL may be disposed on the cover window 100 to cover the upper surface of the cover window 100 in the third direction D3. The protective member PL protects the upper surface of the cover window 100. A first adhesive layer PSA1 may be disposed on the lower surface of the protective member PL to be attached to the cover window 100.

The cover window 100 may be disposed on the display panel 200 to cover the upper surface of the display panel 200 in the third direction DR3. The cover window 100 protects the upper surface of the display panel 200. The cover window 100 may have a light-transmitting portion and a light-blocking portion.

The cover window 100 may include a material with high light transmittance. The cover window 100 may include a polymer resin, such as polyimide or glass. A second adhesive layer PSA2 may be disposed on the lower surface of the cover window 100.

The polarizing member PF may be disposed on the display panel 200. The polarizing member PF can reduce or prevent deterioration of image visibility of the display panel 200 due to reflection of external light. The polarizing member PF may include a linear polarizer and a retardation film, such as a λ/4 (quarter-wave) plate. The retardation film may be disposed on the display panel 200, and the linear polarizer may be disposed on the retardation film. The cover window 100 may be disposed on the polarizing member PF. A third adhesive layer PSA3 may be disposed on the upper surface of the polarizing member PF, and accordingly, the second adhesive layer PSA2 comes into contact with the third adhesive layer PSA3 to attach the polarizing member PF to the lower surface of the cover window 100.

The display panel 200 may be disposed under the polarizing member PF. The display panel 200 may have a rectangular shape having sides in the first direction D1 and sides in the second direction D2 when viewed from the top. In the display panel 200, the corners at where the sides in the first direction D1 meet the sides in the second direction D2 may be formed at a right angle or may be rounded with a curvature (e.g., a predetermined curvature). The display panel 200 may have a polygonal shape other than a rectangular shape, a circular shape, an oval shape, or an irregular shape when viewed from the top.

The display panel 200 may have a display area at where a plurality of emission areas at where light is emitted is arranged and a non-display area disposed around the display area. The non-display area may surround (e.g., may extend around a periphery of) the display area. A plurality of display pads may be disposed in the non-display area at one edge of the display panel 200. A bending area at where a part of the display panel 200 may be bent may be formed in the display panel 200. The bending area may be formed between the support member 400 and the spacer 500.

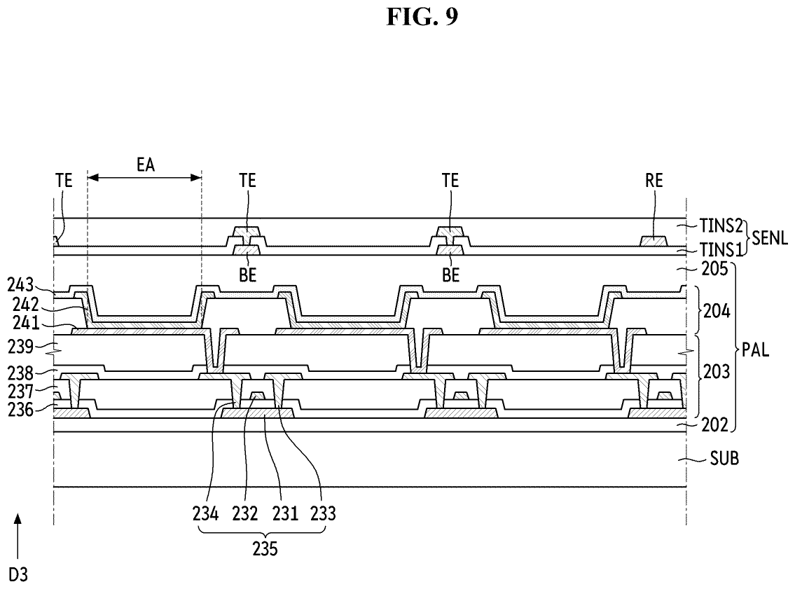

The display panel 200 may include a substrate SUB, a display unit PAL, and a sensor unit SENL (see, e.g., FIG. 9).

The substrate SUB may be made of an insulating material, such as glass, quartz, and a polymer resin. The substrate SUB may be a rigid substrate or a flexible substrate that can be bent, folded, rolled, and so on.

The display unit PAL may be disposed on the substrate SUB. The display unit PAL may be a layer having a plurality of emission areas at where light is emitted. The display unit PAL may include a buffer film, a thin-film transistor layer on which thin-film transistors are disposed, a light-emitting element layer configured to emit light, and an encapsulating layer for encapsulating the light-emitting element layer.

The sensor unit SENL may be disposed on the display unit PAL. The sensor unit SENL may include sensor electrodes and may sense a user's touch.

FIG. 9 is a cross-sectional view of the display panel 200 shown in FIG. 8.

Referring to FIG. 9, the display unit PAL may include a buffer film (or buffer layer) 202, a thin-film transistor layer 203, a light-emitting element layer 204, and an encapsulation layer 205.

The buffer layer 202 may be formed on the substrate SUB. The buffer layer 202 may be formed on the substrate SUB to protect thin-film transistors 235 and the light-emitting elements from moisture permeating through the substrate SUB, which may be susceptible to moisture permeation. The buffer layer 202 may be formed of a plurality of inorganic layers alternately stacked on one another. For example, the buffer layer 202 may be made of multiple layers in which one or more inorganic layer of a silicon oxide layer (SiO^{x}), a silicon nitride layer (SiN^{x}) and SiON are alternately stacked on one another. In some embodiments, the buffer layer 202 may be omitted.

The thin-film transistor layer 203 is formed on the buffer layer 202. The thin-film transistor layer 203 includes thin-film transistors 235, a gate insulating layer 236, an interlayer dielectric layer 237, a protective film 238, and an organic film 239.

Each of the thin-film transistor 235 includes an active layer 231, a gate electrode 232, a source electrode 233, and a drain electrode 234. In FIG. 9, the thin-film transistors 235 are implemented as top-gate transistors in which the gate electrode 232 is located above the active layer 231. It is, however, to be understood that the present disclosure is not limited thereto. For example, the thin-film transistors 235 may be implemented as bottom-gate transistors in which the gate electrode 232 is located below the active layer 231 or as double-gate transistors in which the gate electrodes 232 are disposed both above and below the active layer 231.

The active layer 231 is formed on the buffer layer 202. The active layer 231 may be formed of a silicon-based semiconductor material or an oxide-based semiconductor material. For example, the active layer 231 may be formed of polycrystalline silicon, amorphous silicon, or an oxide semiconductor. A light-blocking layer for blocking external light incident on the active layer 231 may be formed between the buffer layer 202 and the active layer 231.

The gate insulating layer 236 may be formed on the active layer 231. The gate insulating layer 236 may be formed of an inorganic layer, for example, a silicon oxide layer (SiOₓ), a silicon nitride layer (SiNₓ), or a multilayer thereof.

The gate electrodes 232 may be formed on the gate insulating layer 236. The gate electrodes 232 and the gate lines may be made of a single layer or multiple layers of one of molybdenum (Mo), aluminum (AI), chromium (Cr), gold (Au), titanium (Ti), nickel (Ni), neodymium (Nd), and copper (Cu) or an alloy thereof.

The interlayer dielectric layer 237 may be formed over the gate electrodes 232 and the gate lines. The interlayer dielectric layer 237 may be formed of an inorganic layer, for example, a silicon oxide layer (SiOx), a silicon nitride layer (SiNx), or a multilayer thereof.

The source electrodes 233 and the drain electrodes 234 may be formed on the interlayer dielectric layer 237. Each of the source electrodes 233 and the drain electrodes 234 may be connected to the active layer 231 through a contact hole (e.g., a contact opening) penetrating through (or extending through) the gate insulating layer 236 and the interlayer dielectric layer 237. The source electrode 233 and the drain electrode 234 may be made of a single layer or multiple layers of one of molybdenum (Mo), aluminum (AI), chromium (Cr), gold (Au), titanium (Ti), nickel (Ni), neodymium (Nd), and copper (Cu) or an alloy thereof.

The protective film 238 may be formed on the source electrode 233 and the drain electrode 234 to insulate the thin-film transistors 235. The protective film 238 may be formed of an inorganic layer, for example, a silicon oxide layer (SiOₓ), a silicon nitride layer (SiNₓ), or a multilayer thereof.

The organic film 239 may be formed on the protective film 238 to provide a flat surface over the thin-film transistors 335 having difference levels. The organic film 239 may be implemented as an organic layer, such as an acryl resin, an epoxy resin, a phenolic resin, a polyamide resin, and a polyimide resin.

The light-emitting element layer 204 is formed on the thin-film transistor layer 203. The light-emitting element layer 204 includes the light-emitting elements and a bank.

The light-emitting elements and the bank are formed on the organic film 239. An organic light-emitting element including an anode electrode 241, an emissive layer 242, and a cathode electrode 243 is employed as an example of the light-emitting elements.

The anode electrode 241 may be formed on the organic film 239. The anode electrode 241 may be connected to the source electrode 233 of the thin-film transistor 235 via a contact hole (e.g., a contact hole) penetrating through (or extending through) the protective film 238 and the organic film 239.

The bank may be formed to cover an edge of the anode electrode 241 on the organic film 239 to define the emission areas EA of the pixels. For example, the bank may define the emission areas EA of the pixels. In each of the pixels, the anode electrode 241, the emissive layer 242, and the cathode electrode 243 are sequentially stacked on one another so that holes from the anode electrode 241 and electrons from the cathode electrode 243 combine in the emissive layer 242 to emit light.

The emissive layer 242 is formed on the anode electrode 241 and the bank. The emissive layer 242 may be an organic emissive layer. The emissive layer 242 may emit one of red light, green light, and blue light. In some embodiments, the emissive layer 242 may be a white emissive layer that emits white light. In such an embodiment, the red emissive layer, the green emissive layer, and the blue emissive layer may be stacked on one another or may be formed commonly across the pixels as a common layer. In such an embodiment, the display panel 200 may further include additional color filters for representing (e.g., emitting or displaying) red, green, and blue colors.

The emissive layer 242 may include a hole transporting layer, a light-emitting layer, and an electron transporting layer. In addition, the emissive layer 242 may be formed as a tandem structure including two or more stacks, in which case a charge generating layer may be formed between the stacks.

The cathode electrode 243 is formed on the emissive layer 242. The cathode electrode 243 may be formed to cover the emissive layer 242. The cathode electrode 243 may be a common layer formed across the pixels.

When the light-emitting element layer 204 is a top-emission type, in which light exits toward the upper side, the anode electrode 241 may be made of a metal material having a high reflectivity, such as a stack structure of aluminum and titanium (Ti/Al/Ti), a stack structure of aluminum and ITO (ITO/AI/ITO), an APC alloy, and a stack structure of the APC alloy and ITO (ITO/APC/ITO). The APC alloy is an alloy of silver (Ag), palladium (Pd) and copper (Cu). The cathode electrode 243 may be formed of a transparent conductive material (TCP), such as ITO and IZO, that can transmit light, or a semi-transmissive conductive material, such as magnesium (Mg), silver (Ag), and an alloy of magnesium (Mg) and silver (Ag). When the cathode electrode 243 is formed of a semi-transmissive conductive material, the light extraction efficiency can be increased by using microcavities.

When the light-emitting element layer 204 is a bottom-emission type, in which light exits toward the lower side, the anode electrode 241 may be formed of a transparent conductive material (TCP), such as ITO and IZO, that can transmit light, or a semi-transmissive conductive material, such as magnesium (Mg), silver (Ag), and an alloy of magnesium (Mg) and silver (Ag). The cathode electrode 243 may be made of a metal material having a high reflectivity, such as a stack structure of aluminum and titanium (Ti/Al/Ti), a stack structure of aluminum and ITO (ITO/AI/ITO), an APC alloy, and a stack structure of the APC alloy and ITO (ITO/APC/ITO). When the anode electrode 241 is formed of a semi-transmissive conductive material, the light extraction efficiency can be increased by using microcavities.

The encapsulation layer 205 is formed on the light-emitting element layer 204. The encapsulation layer 205 prevents permeation of oxygen or moisture into the emissive layer 242 and the cathode electrode 243. To this end, the encapsulation layer 205 may include at least one inorganic film. The inorganic layer may be formed of silicon nitride, aluminum nitride, zirconium nitride, titanium nitride, hafnium nitride, tantalum nitride, silicon oxide, aluminum oxide, or titanium oxide. Further, the encapsulation layer 205 may further include at least one organic film. The organic film may have a thickness sufficient to prevent particles from permeating into the encapsulation layer 205 and entering the emissive layer 242 and the cathode electrode 243. The organic layer may include one of epoxy, acrylate, and urethane acrylate.

The sensor unit SENL may be formed on the encapsulation layer 205. When the sensor unit SENL is formed directly on the encapsulation layer 205, the thickness of the display device 10 can be reduced compared with a display device in which a separate touch panel is attached on the encapsulation layer 205.

The sensor unit SENL may include sensor electrodes for sensing a user's touch by capacitive sensing and touch lines for connecting the pads with the sensor electrodes. For example, the sensor unit SENL can sense a user's touch by self-capacitance sensing or mutual capacitance sensing. In the embodiment shown in FIG. 9, the sensor unit SENL is made of two layers including driving electrodes TE, sensing electrodes RE, and bridges BE connecting between the driving electrodes TE for mutual capacitance sensing.

The bridges BE may be formed on the encapsulation layer 205. The bridges BE may be made of, but are not limited to, a stack structure of aluminum and titanium (Ti/Al/Ti), a stack structure of aluminum and ITO (ITO/AI/ITO), an APC alloy, and a stack structure of the APC alloy and ITO (ITO/APC/ITO). For example, the bridges BE may be made of a single layer of molybdenum (Mo), titanium (Ti), copper (Cu), aluminum (AI), or ITO.

A first sensing insulating film TINS1 is formed over the bridges BE. The first sensing insulating film TINS1 may be formed of an inorganic film, for example, a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may be formed as, but are not limited to, a stack structure of aluminum and titanium (Ti/Al/Ti), a stack structure of aluminum and ITO (ITO/AI/ITO), an APC alloy, and a stack structure of the APC alloy and ITO (ITO/APC/ITO). For example, the driving electrodes TE and the sensing electrodes RE may be made of a single layer of molybdenum (Mo), titanium (Ti), copper (Cu), aluminum (AI), or ITO.

Contact holes (e.g., contact openings) may be formed in the first sensing insulating film TINS1 which penetrate (or extend through) the first sensing insulating film TINS1 to expose the bridges BE. The driving electrodes TE may be connected to the bridges BE through the contact holes.

A second sensing insulating film TINS2 is formed over the driving electrodes TE and the sensing electrodes RE. The second sensing insulating film TINS2 may provide a flat surface over the driving electrodes TE, the sensing electrodes RE, and the bridges BE, which have different heights. The second sensing insulating film TINS2 may be formed of an organic layer, such as an acryl resin, an epoxy resin, a phenolic resin, a polyamide resin, and a polyimide resin.

The bridges BE connecting the adjacent driving electrodes TE to each other may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections, while the sensing electrodes RE may be electrically connected with one another in a direction, and the driving electrodes TE may be electrically connected with one another in another direction.

The bending protective member BPL may be disposed on the bending area of the display panel 200. For example, the bending protective member BPL may be disposed on the upper surface of the display panel 200 to cover the bending area. A part of the bending protective member BPL may partially overlap the display area and a pad area of the display panel 200, but the present disclosure is not limited thereto. The bending protective member BPL may overlap only with the bending area.

The bending protective member BPL can protect the bending area of the display panel 200. The bending protective member BPL can protect a conductive layer in the bending area of the display panel 200. Lines for transmitting driving signal to the display panel 200 may be disposed in the conductive layer in the bending area of the display panel 200. Depending on the arrangement of the bending protective member BPL, the tensile stress applied to the conductive layer can be reduced by controlling the position of a neutral plane (e.g., a stress neutral plane) when the display panel 200 is bent. In addition, the bending protective member BPL can protect the bending area of the display panel 200 from static electricity introduced from the outside.

The base member may be disposed on the lower surface of the display panel 200 in the third direction D3. The base member can absorb external shock transmitted to the display panel 200 from below. For example, the base member can protect the display panel 200 from external impact. The base member may include a base film 300, a fourth adhesive layer PSA4, and a fifth adhesive layer PSA5.

The base film 300 may be made of a single layer or multiple layers. For example, the base film 300 may be formed of a polymer resin, such as polyurethane, polycarbonate, polypropylene, and polyethylene, or may be formed of a material having elasticity, such as a rubber and a sponge obtained by foaming a urethane-based material or an acrylic-based material.

The fourth adhesive layer PSA4 may be disposed on the upper surface of the base film 300 in the third direction D3. For example, the fourth adhesive layer PSA4 may be disposed between the base film 300 and the display panel 200. When the fourth adhesive layer PSA4 is formed integrally with the base film 300, and the fourth adhesive layer PSA4 comes into contact with the lower surface of the display panel 200, the base film 300 may be attached to the lower surface of the display panel 200 by the fourth adhesive layer PSA4.

The fifth adhesive layer PSA5 may be disposed on the lower surface of the base film 300 in the third direction D3. For example, the fifth adhesive layer PSA5 may be disposed between the base film 300 and the support member 400 and between the base film 300 and the spacer 500. When the fifth adhesive layer PSA5 is formed integrally with the base film 300, and the fifth adhesive layer PSA5 contacts the upper surface of the support member 400 and the upper surface of the spacer 500 (e.g., the upper surface before the display panel is bent) so that the support member 400 and the spacer 500 can be attached to the lower surface of the base film 300. The fifth adhesive layer PSA5 may have a removed area formed by removing a part of the fifth adhesive layer PSA5.

The support member 400 may be disposed on the lower surface of the base film 300. The support member 400 may be a rigid member that does not easily change its shape or volume due to external pressure. The support member 400 is disposed under the display panel 200, and thus, it can support the display panel 200.

According to embodiment of the present disclosure, the support member 400 may be a metal plate. For example, the support member 400 may be a metal plate and may be made of metal or metal alloy. The support member 400 may include, but is not limited to, copper (Cu), aluminum (Al), stainless steel (SUS), and/or an alloy thereof.

According to another embodiment, the support member 400 may be a polymer including carbon fiber or glass fiber. In such an embodiment, because the support member 400 is formed of a polymer including carbon fiber or glass fiber, electromagnetic signals of a digitizer member in the display device 10 can pass through. Therefore, the support member 400 can support the display panel 200 without reducing the touch sensitivity of the digitizer member.

The support member 400 may have an opening 410 located in the folding area FDA so that it can be more easily bent in the folding area FDA. The opening 410 may be formed in a lattice pattern in which a portion of the support member 400 is opened (or removed). When the support member 400 includes the lattice pattern disposed in the folding area FDA, the support member 400 can be more easily bent when the display device 10 is folded.

In some embodiments, the display device 10 may further include a digitizer member. The digitizer member may be disposed under the support member 400. The digitizer member may include electrode patterns for sensing proximity or contact of an electronic pen, such as a stylus pen supporting an electromagnetic resonance (EMR) technology. The digitizer member may detect a magnetic field or an electromagnetic signal emitted from the electronic pen based on the electrode patterns and may determine touch coordinates of the point where the detected magnetic field or electromagnetic signal is largest.

Magnetic metal powder may be disposed under the digitizer member. In this instance, magnetic field or electromagnetic signals passing through the digitizer member may flow into the magnetic metal powder. Therefore, by virtue of the magnetic metal powder, the magnetic field or electromagnetic signals from the digitizer member may be suppressed from exiting to the bottom of the display device 10.

The spacer 500 may be disposed on the lower surface of the base film 300 (e.g., the lower surface before the display panel is bent). The spacer 500 may be spaced apart from the support member 400. For example, the spacer 500 may be spaced apart from the support member 400 such that the bending area of the display panel 200 is located between the spacer and the support member 400. The spacer 500 may be used to fill the empty space between the display panel 200 and the support member 400 when the display panel 200 is bent to prevent the bending area of the display panel 200 from being excessively deformed. The spacer 500 may contact the support member 400 when the display panel 200 is bent.

A sixth adhesive layer PSA6 may be disposed between the support member 400 and the spacer 500. When the sixth adhesive layer PSA6 may be formed integrally with the spacer 500, and the sixth adhesive layer PSA6 contacts the support member 400, the spacer 500 may be attached to the support member 400.

The cover member 600 may be disposed on the bending protective member BPL and the display panel 200 to cover a part of the bending protective member BPL and a part of the display panel 200. The cover member 600 may extend from the bending protective member BPL to an end of the display panel 200 in the first direction D1. The cover member 600 can protect a part of the bending protective member BPL and a part of the display panel 200 from external impact.

Hereinafter, a method of fabricating a display device 10 according to an embodiment of the present disclosure will be described with reference to the accompanying drawings.

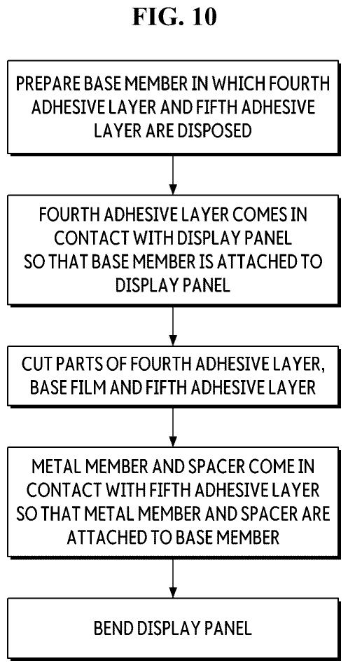

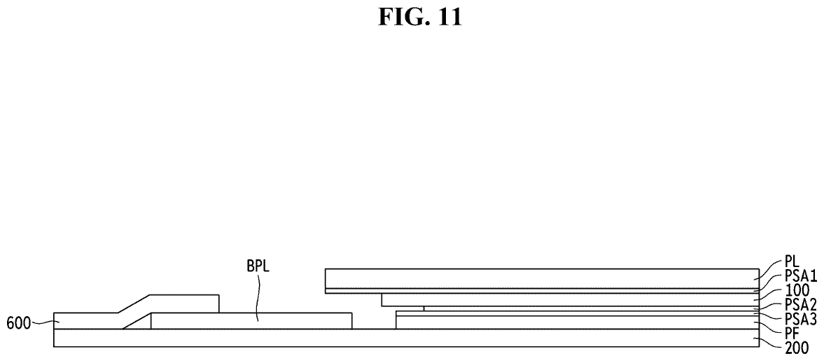

FIG. 10 is a flowchart describing steps of a method of fabricating the display device 10 according to an embodiment of the present disclosure. FIG. 11 is a view of a display panel 200 prepared according to a method of fabricating a display device 10.

Referring to FIGS. 10 and 11, the method of fabricating the display device 10 according to an embodiment of the present disclosure may include preparing a display panel 200.

As shown in FIG. 11, a protective member PL, a cover window 100, a polarizing member PF, a bending protective member BPL, and a cover member 600 may be disposed on the prepared display panel 200.

The protective member PL, the cover window 100, the polarizing member PF, the bending protective member BPL, and the cover member 600 may be disposed as follows: Initially, the method may include disposing the polarizing member PF on the display panel 200.

After the polarizing member PF is disposed on the display panel 200, the method may include disposing the cover window 100 on the polarizing member PF. The cover window 100 may be attached on the polarizing member PF when the third adhesive layer PSA3 formed integrally with the polarizing member PF and the second adhesive layer PSA2 formed integrally with the cover window 100 come into contact with each other.

After the cover window 100 is disposed on the polarizing member PF, the method may include disposing the protective member PL on the cover window 100. The protective member PL may be attached on the cover window 100 when the first adhesive layer PSA1 formed integrally with the protective member PL comes into contact with the cover window 100.

After the protective member PL is disposed on the cover window 100, the method may include disposing the bending protective member BPL in a bending area of the display panel 200. The disposing of the bending protective member BPL may be performed after the protective member PL is disposed on the cover window 100 but may also be performed before the disposing of the polarizing member PF on the display panel 200.

After the bending protective member BPL is disposed in the bending area of the display panel 200, the method may include disposing the cover member 600 on the bending protective member BPL. The cover member 600 may be disposed to cover a part of the bending protective member BPL and a part of the display panel 200.

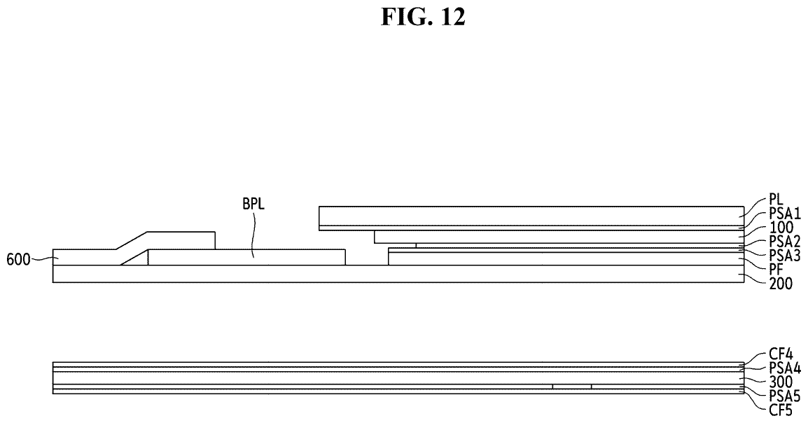

FIG. 12 is a view of a base member is disposed on the display panel 200 according to the method of fabricating the display device 10.

Referring to FIG. 12, after the display panel 200 is prepared, the method may include preparing the base member in which a base film 300, a fourth adhesive layer PSA4, and a fifth adhesive layer PSA5 are integrally formed. The fourth adhesive layer PSA4 may be disposed on the prepared base film 300, and the fifth adhesive layer PSA5 may be disposed on the lower surface of the base film 300. A fourth cover film CF4 covering the fourth adhesive layer PSA4 may be disposed on the upper surface of the fourth adhesive layer PSA4, and a fifth cover film CF5 covering the fifth adhesive layer PSA5 may be disposed on the lower surface of the fifth adhesive layer PSA5. The prepared base member may be disposed under the display panel 200.

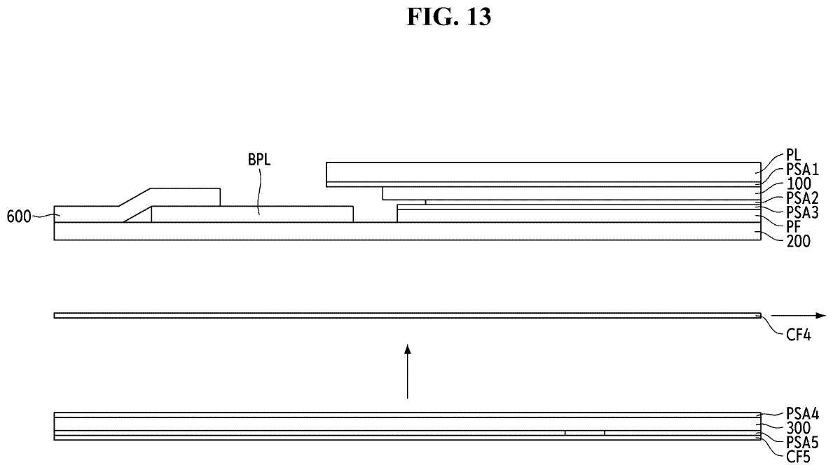

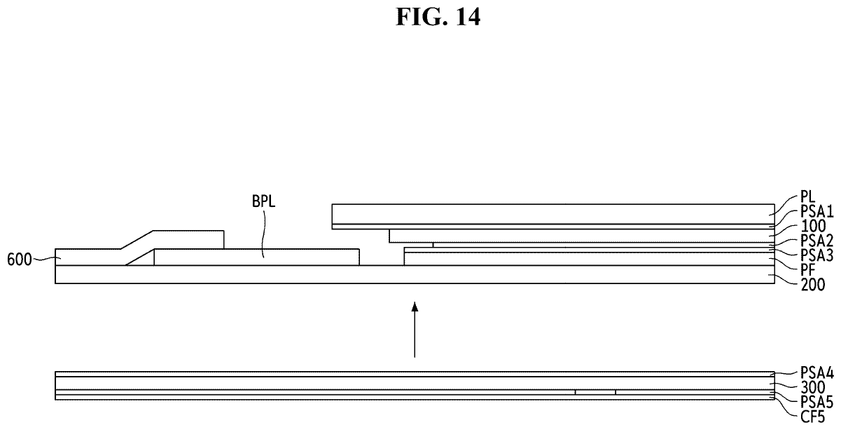

FIG. 13 is a view of removing the fourth cover film CF4 according to the method of fabricating the display device 10. FIG. 14 is a view showing that the base member is disposed on the display panel 200 according to the method of fabricating the display device 10.

Referring to FIGS. 13 and 14, after the fourth cover film CF4 is removed from the base member disposed under the display panel 200, the method may include bringing the fourth adhesive layer PSA4 disposed on the upper surface of the base film 300 into contact with the lower surface of the display panel 200. When the fourth adhesive layer PSA4 is in contact with the lower surface of the display panel 200, the base film 300 may be attached to the lower surface of the display panel 200.

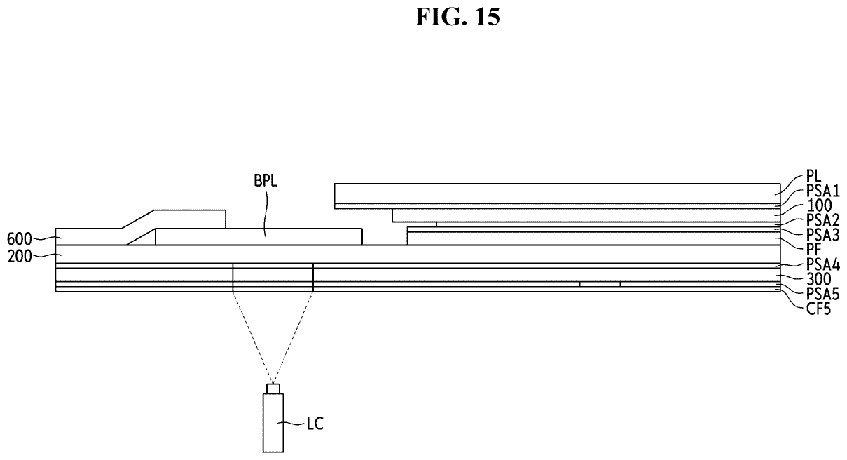

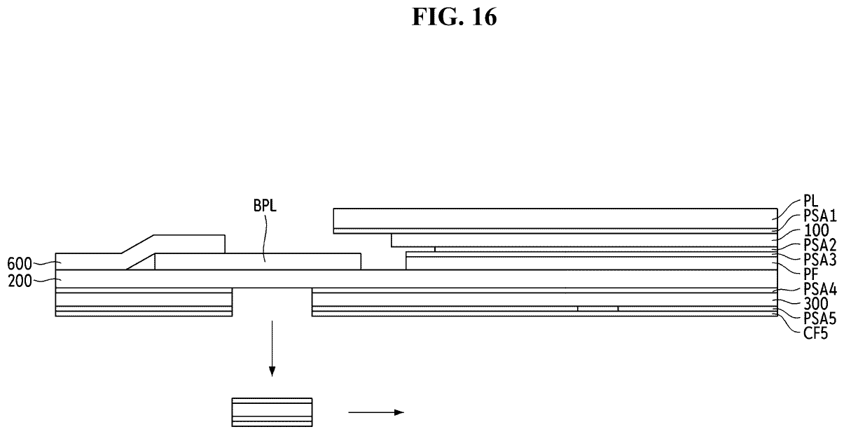

FIG. 15 is a view of a part of the base member being cut according to the method of fabricating the display device 10. FIG. 16 is a view of the cut part of the base member being removed according to the method of fabricating the display device 10.

Referring to FIGS. 15 and 16, after the base member is attached under the display panel 200, the method may include removing a part of the base member. In the removing a part of the base member, the removed part of the base member may be positioned under the bending area of the display panel 200. The part of the base member may be cut by a laser irradiated from a laser cutter LC, and the cut part of the base member may be removed by pulling it out of the base member. When the part of the base member is removed, parts of the base film 300 and parts of the fourth adhesive layer PSA4 and the fifth adhesive layer PSA5 formed integrally with the base film 300 may be removed together.

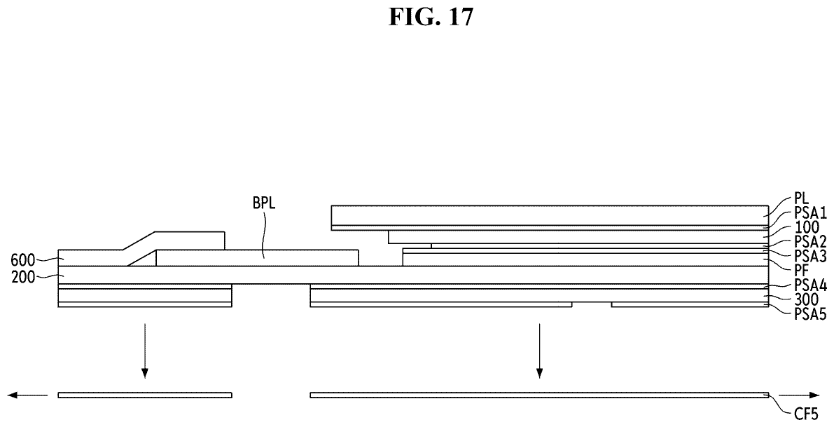

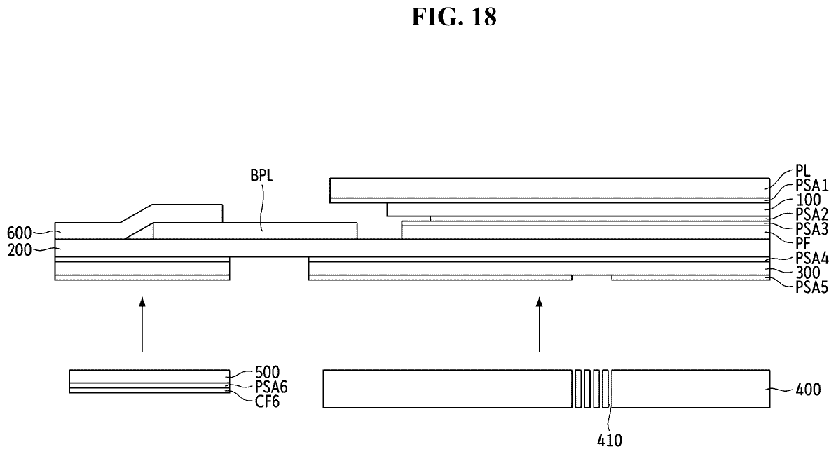

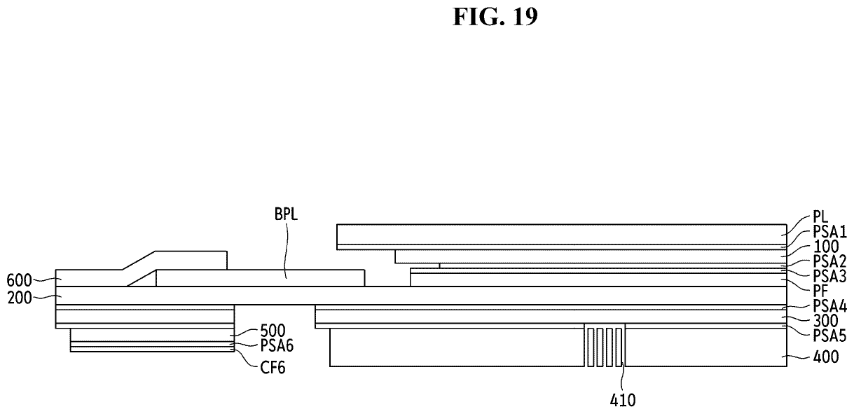

FIG. 17 is a view of the fifth cover film CF5 being removed according to the method of fabricating the display device 10. FIGS. 18 and 19 are views of a support member 400 and a spacer 500 be9ing attached to the base member according to the method of fabricating the display device 10.

Referring to FIGS. 17 to 19, after the fifth cover film CF5 have been from the base member disposed under the display panel 200, the method may include preparing and disposing the support member 400 and the spacer 500 under the base member. When the upper surfaces of the support member 400 and the spacer 500 disposed under the base member come in contact with the lower surface of the fifth adhesive layer PSA5, the support member 400 and the spacer 500 can be attached to the base film 300.

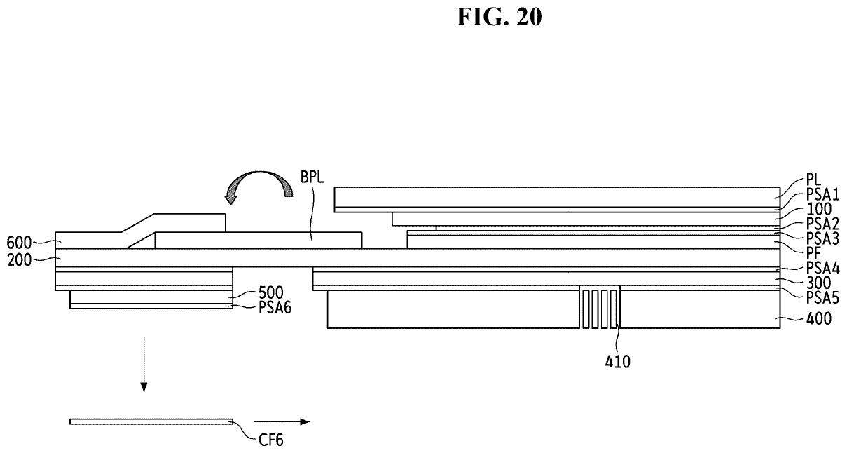

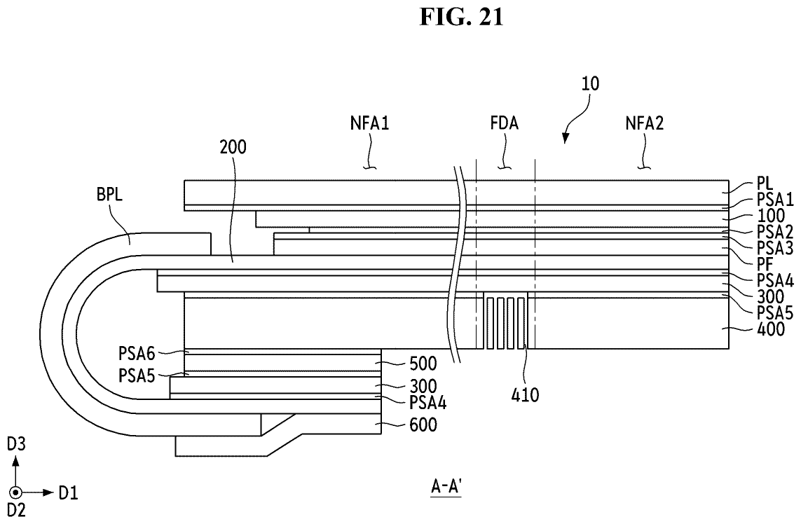

FIG. 20 is a view of the sixth cover film CF6 being removed and the display panel 200 being bent according to the method of fabricating the display device 10. FIG. 21 is a view of the display panel 200 in the bent state such that the support member 400 and the spacer 500 are in contact with each other according to the method of fabricating the display device 10.

Referring to FIG. 21, after the support member 400 and the spacer 500 are attached to the base member, the method may include removing the sixth cover film CF6 covering the sixth adhesive layer PSA6 formed integrally with the spacer 500.

After the sixth cover film CF6 is removed, the display panel 200 is bent so that the sixth adhesive layer PSA6 comes into contact with the support member 400 so that the spacer 500 may be attached to the support member 400.

In the display device 10 and the method according to embodiments of the present disclosure, which is configured and fabricated as described above, the fourth adhesive layer PSA4 that attaches the base film 300 to the display panel 200, and the fifth adhesive layer PSA5 that attaches the base film 300 to the support member 400 and the spacer 500 are formed integrally with the base film 300 so that the process of stacking a separate adhesive layer on the support member 400 and the spacer 500 can be omitted. As a result, the process of disposing the base film 300, the support member 400, and the spacer 500 on the display panel 200 can be simplified.

The display device according to one embodiment of the present disclosure can be applied to various electronic devices. The electronic device according to the one embodiment of the present disclosure includes the display device described above, and may further include modules or devices having additional functions in addition to the display device.

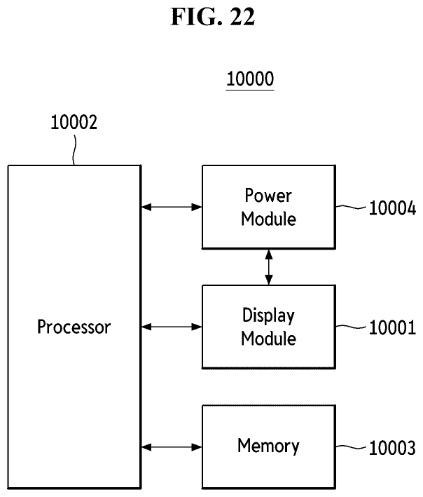

FIG. 22 is a block diagram of an electronic device according to one embodiment of the present disclosure.

Referring to FIG. 22, the electronic device 10000 according to one embodiment of the present disclosure may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), and a controller.

The memory 10003 may store data information necessary for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to the one embodiment of the present disclosure may be included in the display device according to the embodiments of the present disclosure. In addition, some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

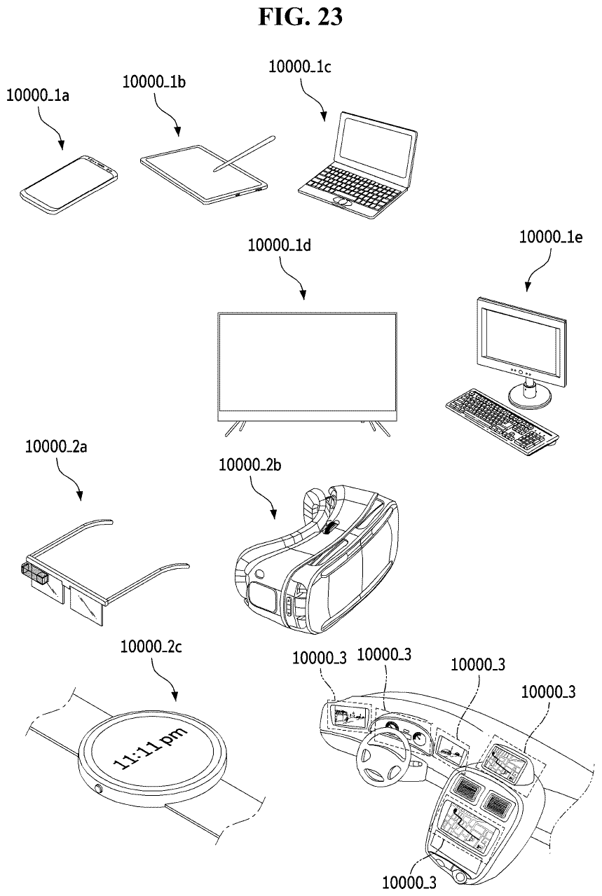

FIG. 23 is a schematic diagram of an electronic device according to various embodiments of the present disclosure.

Referring to FIG. 23, various electronic devices to which display devices according to embodiments of the present disclosure are applied may include not only image display electronic devices such as a smart phone 10000_1a, a tablet PC (personal computer) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a CID (Center Information Display) and a room mirror display arranged on a dashboard, center fascia, and dashboard of an automobile.

It should be understood, however, that the aspects and features of the present disclosure are not limited to those set forth herein. The above and other aspects and features of the present disclosure will become more apparent to one of ordinary skill in the art to which the present disclosure pertains by referencing the claims, with equivalents thereof to be included therein.

What is claimed is:

1. A display device comprising:
a display panel;
a base member on a surface of the display panel;
a support member on a surface of the base member; and
a spacer on the surface of the base member, and
wherein the base member comprises:
a base film;
a fourth adhesive layer between the base film and the display panel; and
a fifth adhesive layer between the base film and the support member and between the base film and the spacer, and
wherein the base film, the fourth adhesive layer, and the fifth adhesive layer are integrally formed.

2. The display device of claim 1, further comprising:
a polarizing member on a surface of the display panel opposite to the base member;
a cover window on a surface of the polarizing member opposite to the display panel;
a protective member on a surface of the cover window opposite to the polarizing member;
a first adhesive layer between the protective member and the cover window;
a second adhesive layer between the cover window and the polarizing member and on a surface of the cover window facing the polarizing member; and
a third adhesive layer between the cover window and the polarizing member and on the surface of the polarizing member facing the cover window.

3. The display device of claim 1, further comprising a sixth adhesive layer between the support member and the spacer,
wherein the display panel has a bending area at where the display panel is configured to be bent, and
wherein the support member and the spacer contact each other when the display panel is bent.

4. The display device of claim 3, wherein the bending area of the display panel is between the support member and the spacer.

5. The display device of claim 3, further comprising:
a bending protective member on the bending area of the display panel; and
a cover member covering a part of the bending protective member and a part of the display panel.

6. The display device of claim 1, wherein the fifth adhesive layer has an opening therein formed by removing a part of the fifth adhesive layer, and
wherein the support member has an opening therein.

7. The display device of claim 6, wherein the opening in the support member corresponds to the opening in the fifth adhesive layer.

8. A method of fabricating a display device, the method comprising:
preparing a base member comprising a base film, a fourth adhesive layer, and a fifth adhesive layer integrally formed together;
attaching the base film to a display panel by the fourth adhesive layer; and
attaching a support member and a spacer to the base film by the fifth adhesive layer.

9. The method of claim 8, wherein the base member comprises:
a fourth cover film covering the fourth adhesive layer; and
a fifth cover film covering the fifth adhesive layer, and
wherein the attaching the base film to the display panel comprises:
removing the fourth cover film; and
bringing the fourth adhesive layer into contact with the display panel.

10. The method of claim 8, further comprising, after the attaching the base film to the display panel, removing a part of the base film.

11. The method of claim 10, wherein the display panel has a bending area at where a part of the display panel is configured to be bent, and
wherein the removing the part of the base film comprises removing the base film corresponding to the bending area of the display panel.

12. The method of claim 11, wherein the removing the part of the base film comprises: removing the base film on the bending area of the display panel along with the fourth adhesive layer and the fifth adhesive layer on the bending area of the display panel.

13. The method of claim 9, wherein the attaching the support member and the spacer to the base film comprises:
removing the fifth cover film; and
bringing the support member and the spacer into contact with the fifth adhesive layer.

14. The method of claim 11, further comprising:
after the attaching the support member and the spacer to the base film, bending a part of the display panel; and
attaching the spacer to the support member.

15. The method of claim 14, wherein the spacer comprises:
a sixth adhesive layer formed integrally with the spacer; and
a sixth cover film covering the sixth adhesive layer,
wherein the attaching the spacer to the support member comprises:
removing the sixth cover film; and
bringing the sixth adhesive layer into contact with the support member.

16. The method of claim 8, further comprising:
disposing a polarizing member on the display panel;
disposing a cover window on the polarizing member; and
disposing a protective member on the cover window.

17. The method of claim 16, wherein the polarizing member comprises a third adhesive layer formed integrally with the polarizing member,
wherein the cover window comprises a second adhesive layer formed integrally with the cover window, and
wherein the disposing the cover window on the polarizing member comprises bringing the second adhesive layer into contact with the third adhesive layer.

18. The method of claim 16, wherein the protective member comprises a first adhesive layer formed integrally with the protective member, and
wherein the disposing the protective member on the cover window comprises bringing the first adhesive layer into contact with the cover window.

19. The method of claim 16, further comprising:
disposing a bending protective member on the display panel; and
disposing a cover member to cover a part of the bending protective member and a part of the display panel,
wherein the bending protective member and the cover member are on a surface of the display panel on which the polarizing member is arranged.

20. An electronic device comprising:
a display panel;
a base member on a surface of the display panel;
a support member on a surface of the base member; and
a spacer disposed on the surface of the base member, and
wherein the base member comprises:
a base film;
a fourth adhesive layer between the base film and the display panel; and
a fifth adhesive layer between the base film and the support member and between the base film and the spacer, and
wherein the base film, the fourth adhesive layer, and the fifth adhesive layer are integrally formed.
